(19) United States
(12) Patent Application Publication
(10) Pub. No.: US 2025/0140571 A1
(43) Pub. Date: May 1, 2025

(54) POLYSILICON GATE ETCH METHOD

(71) Applicant: Shanghai Huali Integrated Circuit Corporation, Shanghai (CN)

(72) Inventors: Jin XU, Shanghai (CN); Zaifeng TANG, Shanghai (CN); Kaiqu ANG, Shanghai (CN)

(73) Assignee: Shanghai Huali Integrated Circuit Corporation, Shanghai (CN)

(21) Appl. No.: 18/778,752

(22) Filed: Jul. 19, 2024

(30) Foreign Application Priority Data
Oct. 27, 2023 (CN) 202311414207.9

(51) Int. Cl. H01L 21/3213; H01L 21/28

(52) U.S. Cl. CPC H01L 21/32137; H01L 21/28035; H01L 21/32139

(57) ABSTRACT

The present disclosure discloses a polysilicon gate etch method, wherein base on the property that bombarding a photoresist with a HBr plasma cloud can cause a qualitative change in bonding energy of the photoresist, a linewidth cure step using only HBr is added to a polysilicon gate etch process. An injection flow rate of an HBr gas in the linewidth cure step is adjusted according to the needs of process integration, to reduce a linewidth difference between different polysilicon gate structures, thereby optimizing and quantifying post-etch critical dimensions of the polysilicon gate structures of different sizes. Accordingly, the problem of an unchangeable linewidth difference between different polysilicon gate structures after polysilicon etch in case of current fixed mask and lithography condition may be solved.

### CROSS-REFERENCE TO RELATED APPLICATIONS

This application claims priority to Chinese patent application No. 202311414207.9, filed on Oct. 27, 2023, the disclosure of which is incorporated herein by reference in its entirety.

### TECHNICAL FIELD

The present disclosure relates to semiconductor manufacturing technologies, and in particular, to a polysilicon gate etch method.

### BACKGROUND

An etch process is one of the most critical processes in the manufacturing of an integrated circuit, and mainly functions to accomplish a final transfer and finalization of a pattern on a silicon wafer during a lithography process. The etch requirements depend on the type of a feature pattern to be fabricated, such as a polysilicon gate, a shallow trench, a metal mask layer, or a dielectric via. A polysilicon gate etch process is of the highest importance in an etch process, as the critical dimension (CD) thereof is the minimum among all the layers, and thus is most crucial. Generally, according to different film structures, the polysilicon gate etch process may include steps shown in FIG. 1: bottom anti reflection coating (BARC) opening (BARC opening), hard mask (HM) opening (HM opening), hard mask (HM) trim (HM trim), photoresist strip (PR strip), polysilicon etch (Poly etch), etc. The polysilicon etch is jointly completed by three steps of etch: BT (silicon oxide etch), ME1 (first polysilicon etch), and ME2 (second polysilicon etch), in order to obtain a better polysilicon gate morphology.

In an existing semiconductor production process, the dimension (CD) of each structure at each level after etch is determined by a mask and a lithography condition, and the etch process is basically unable to regulate a dimension difference between different linewidth structures, as shown in FIG. 2.

### BRIEF SUMMARY

The polysilicon gate etch method provided by the present disclosure includes the following steps:
S1: sequentially forming a gate oxide layer, a polysilicon layer, a hard mask layer, a bottom anti reflection coating, and a photoresist on a silicon substrate;
S2: photoetching the photoresist according to design linewidths of polysilicon gates at various positions on a wafer;
S3: injecting an etch gas into an etch chamber, to remove the bottom anti reflection coating outside a polysilicon gate area by etch and retain the bottom anti reflection coating in the polysilicon gate area;
S4: injecting only an HBr gas into the etch chamber at a cure flow rate as an etch gas, to etch the bottom anti reflection coating, so that the anti-reflection coating and the photoresist in the polysilicon gate area are further narrowed, reducing a width difference between the anti-reflection coatings on the polysilicon gates at various positions on the wafer;
S5: etching the hard mask layer, to remove the hard mask layer not covered by the bottom anti reflection coating and retain the hard mask layer covered by the bottom anti reflection coating; and
S6: performing subsequent process steps to complete polysilicon gate etch.

In some examples, step S6 includes the following steps:
S61: performing hard mask layer cure etch to reduce the width of the hard mask layer at each polysilicon gate on the wafer by a corresponding magnitude;
S62: stripping the photoresist and the bottom anti reflection coating, and retaining the hard mask layer; and
S63: etching a polysilicon layer using the hard mask layer as a protective layer, to remove the polysilicon layer not covered by the hard mask layer and retain the polysilicon layer covered by the hard mask layer.

In some examples, the etch gas injected into the etch chamber in step S3 includes an HBr gas.

In some examples, the hard mask layer is composed of at least one silicon oxide layer and/or a silicon nitride layer.

In some examples, components of the bottom anti reflection coating include a body film-forming resin capable of cross-linking, a thermo acid generator, a crosslinking agent, and an organic solvent.

In some examples, the bottom anti reflection coating includes the following raw materials in mass percentages: 5-15% of aryl-containing glycoluril oligomer solution, 0.5-15% of body resin, 0.1-5% of crosslinking agent, 0.1-1% of thermosensitive acid, and the organic solvent of the remaining amount;
where the body resin includes a light-absorbing functional group, a crosslinking functional group, and an auxiliary functional group.

In some examples, in step S4, the cure flow rate is determined by selection based on the design linewidths of the polysilicon gates at various positions on the wafer, and a matrix table of a calibrated HBr gas flow rate and magnitudes of changes in linewidths of different structures after etch; and
the matrix table of the HBr gas flow rate and the magnitudes of changes in linewidths of different structures after etch is calibrated by a DOE experiment method.

In some examples, during step S4, when the cure flow rate of HBr is determined by selection, design linewidths of the polysilicon gates of various structures and at various positions on the wafer are collected before the bottom anti reflection coating is etched;
during step S5, widths of the hard mask layer at the polysilicon gates of various structures on the wafer are collected after the hard mask layer is etched;
a center design linewidth for the current process is determined based on the design linewidths of the polysilicon gates of various structures and at various positions on the wafer that are collected before the bottom anti reflection coating is etched and during step S4 and the widths of the hard mask layer at the polysilicon gates of various structures on the wafer that are collected after the hard mask layer is etched and during step S5; and
the center design linewidth is used as a centerline to establish a process window for the process.

In the polysilicon gate etch method of the present disclosure, based on the property that bombarding a photoresist (PR) with a HBr plasma cloud can cause a qualitative change in bonding energy of the photoresist (for example, 193-nanometer photoresist), a linewidth cure step using only HBr is added to a polysilicon gate etch process. An injection flow rate of an HBr gas in the linewidth cure step is adjusted according to the needs of process integration, to reduce a linewidth difference between different polysilicon gate structures, thereby optimizing and quantifying post-etch critical dimensions of the polysilicon gate structures of different sizes. Accordingly, the problem of an unchangeable linewidth difference between different polysilicon gate structures after polysilicon etch in case of current fixed mask and lithography condition may be solved. In case of the fixed mask and lithography condition, according to the needs of process integration, post-etch linewidth dimensions of the various polysilicon gate structures may be obtained by adjusting a process condition of the polysilicon gate etch, to improve choosability for needs of linewidths after the polysilicon gate etch, significantly saving development costs and development time.

### BRIEF DESCRIPTION OF THE DRAWINGS

In order to more clearly explain the technical solutions of the present disclosure, the drawings required to be used in the present disclosure will be briefly described below. It is obvious that the drawings described below are merely some embodiments of the present disclosure, and those skilled in the art could also obtain other drawings on the basis of these drawings without the practice of inventive effort.

FIG. 1 is a flowchart of an existing polysilicon gate etch process;

FIG. 2 is a schematic diagram of different linewidth structures etched during the existing polysilicon gate etch process;

FIG. 3 is a flowchart of a polysilicon gate etch method according to an embodiment of the present disclosure;

FIG. 4 illustrates a 193-nanometer photoresist bond;

FIG. 5 illustrates a 193-nanometer photoresist bond cured by HBr;

FIG. 6 illustrates the post-etch dimensions of various structures obtained by adjusting a polysilicon gate etch process condition; and

FIG. 7 is a schematic diagram of post-etch linewidths of different lithographic linewidth structures obtained with different HBr amounts.

### DETAILED DESCRIPTION OF THE DISCLOSURE

The technical solutions in the embodiments of the present disclosure will be clearly and completely described below in conjunction with the drawings. Obviously, the described embodiments are only part of the embodiments of the present disclosure, rather than all of the embodiments. Based on the embodiments in the present disclosure, all other embodiments obtained by those skilled in the art without the practice of inventive effort shall fall into the protection scope of the present disclosure.

The terms such as “first” and “second” used in the present application do not indicate any order, quantity, or importance, but are only used to distinguish different constituent parts. The terms such as “include” or “comprise” mean that the components or objects in front of these terms cover the components or objects listed after the terms and equivalents thereof, but does not exclude other components or objects. The terms such as “connection” or “coupling” are not limited to physical or mechanical connections, but may include electrical connections, whether direct or indirect. The terms such as “upper”, “lower”, “left”, “right”, “front”, and “rear” are only used to represent relative positional relationships, which may be changed accordingly after absolute positions of the described objects are changed.

It should be noted that the embodiments or features in the embodiments of the present disclosure can be combined with each other in the case of no conflicts.

### Embodiment I

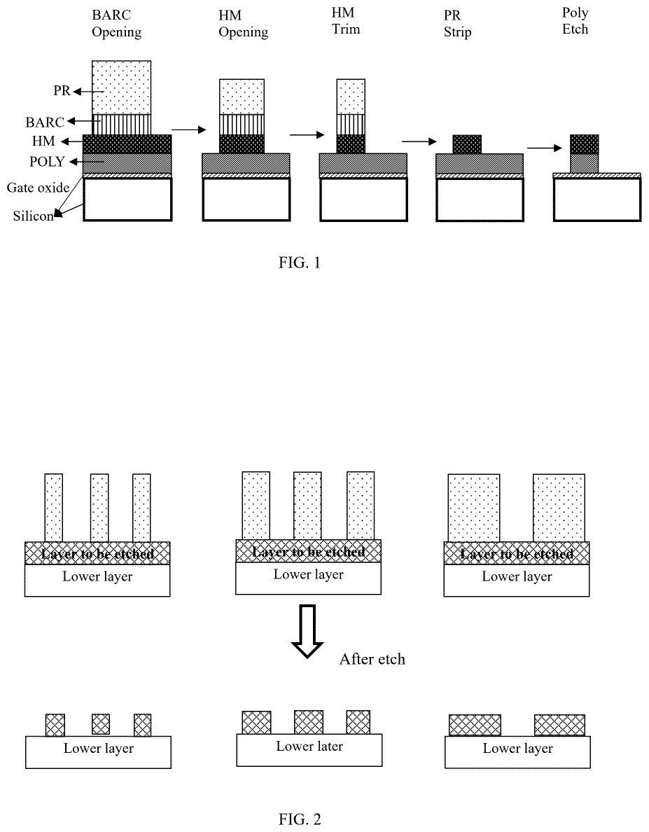

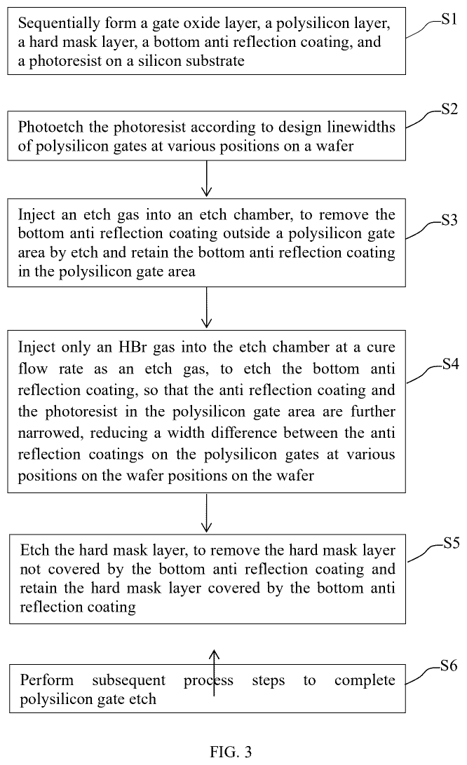

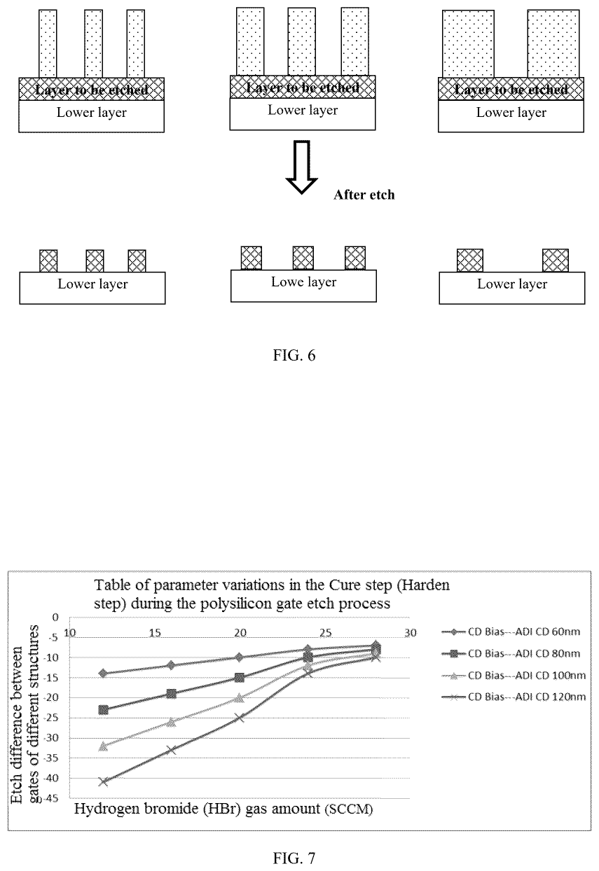

A polysilicon gate etch method, referring to FIG. 3, includes the following steps:
S1: sequentially forming a gate oxide layer, a polysilicon (POLY) layer, a hard mask layer (HM), a bottom anti reflection coating (BARC), and a photoresist (PR) on a silicon substrate, as shown in FIG. 1;
S2: photoetching the photoresist (PR) according to design linewidths of polysilicon gates at various positions on a wafer;
S3: injecting an etch gas into an etch chamber, to remove the bottom anti reflection coating (BARC) outside a polysilicon gate area by etch and retain the bottom anti reflection coating (BARC) in the polysilicon gate area;
S4: injecting only a hydrogen bromide (HBr) gas into the etch chamber at a cure flow rate as an etch gas, to remove the bottom anti reflection coating (BARC) outside the polysilicon gate area by etch and retain the bottom anti reflection coating (BARC) in the polysilicon gate area, where an etch rate of the hydrogen bromide (HBr) gas for the bottom anti reflection coating (BARC) and the photoresist (PR) is much greater than an etch rate for the hard mask layer (HM), so that the bottom anti reflection coating (BARC) and the photoresist in the polysilicon gate area may be further narrowed, and different photoresist (PR) widths lead to a difference in the amount of narrowing in case of the same injection flow rate, i.e., the larger the photoresist (PR) width, the greater the amount of narrowing in case of the same injection flow rate, so that a width difference between the bottom anti reflection coatings (BARCs) and a width difference between the photoresists (PRs) on the polysilicon gates at various positions on the wafer may be reduced, as shown in FIG. 6;
S5: etching the hard mask layer (HM), to remove the hard mask layer (HM) not covered by the bottom anti reflection coating (BARC) and retain the hard mask layer (HM) covered by the bottom anti reflection coating (BARC); and
S6: performing subsequent process steps to complete polysilicon gate etch.

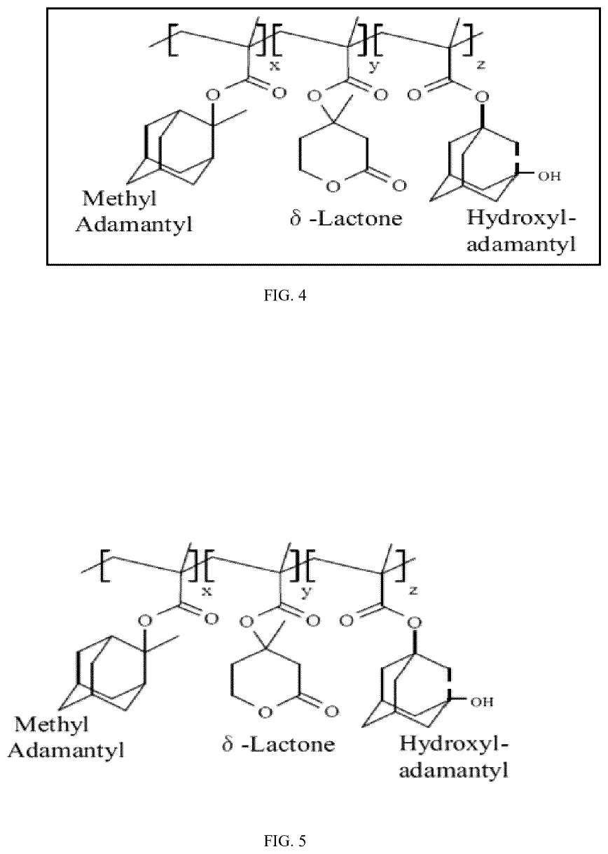

A 193-nanometer photoresist bond is shown in FIG. 4, where hydrogen bromide (HBr) forms a plasma inside the etch chamber, and when a plasma cloud bombards the photoresist (PR), a qualitative change in bonding energy within the photoresist (e.g., 193-nanometer photoresist) is caused, as shown in FIG. 5. Since this reaction is similar to a chemical reaction, it is inconsistent for structures with different linewidths.

In the polysilicon gate etch method of Embodiment I, based on the property that bombarding a photoresist (PR) with a HBr plasma cloud can cause a qualitative change in bonding energy of the photoresist (for example, 193-nanometer photoresist), a linewidth cure step using only HBr is added to a polysilicon gate etch process. An injection flow rate of an HBr gas in the linewidth cure step is adjusted according to the needs of process integration, to reduce a linewidth difference between different polysilicon gate structures, thereby optimizing and quantifying post-etch critical dimensions of the polysilicon gate structures of different sizes. Accordingly, the problem of an unchangeable linewidth difference between different polysilicon gate structures after polysilicon etch in case of current fixed mask and lithography condition may be solved. In case of the fixed mask and lithography condition, according to the needs of process integration, post-etch linewidth dimensions of the various polysilicon gate structures may be obtained by adjusting a process condition of the polysilicon gate etch, to improve choosability for needs of linewidths after the polysilicon gate etch, significantly saving development costs and development time.

### Embodiment II

Based on the polysilicon gate etch method of Embodiment I, step S6 includes the following steps:
S61: performing hard mask layer (HM) cure etch to reduce the width of the hard mask layer (HM) at each polysilicon gate on the wafer by a corresponding magnitude;
S62: stripping the photoresist (PR) and the bottom anti reflection coating (BARC), and retaining the hard mask layer (HM); and
S63: etching a polysilicon layer 12 using the hard mask layer (HM) as a protective layer, to remove the polysilicon layer 12 not covered by the hard mask layer (HM) and retain the polysilicon layer 12 covered by the hard mask layer (HM).

In some examples, the etch gas injected into the etch chamber in step S3 includes a hydrogen bromide (HBr).

In some examples, the hard mask layer is composed of at least one silicon oxide layer and/or a silicon nitride layer.

In some examples, main components of the bottom anti reflection coating (BARC) include a body film-forming resin capable of cross-linking, a thermo acid generator, a crosslinking agent, and an organic solvent.

In some examples, the bottom anti reflection coating (BARC) includes the following raw materials in mass percentages: 5-15% of aryl-containing glycoluril oligomer solution, 0.5-15% of body resin, 0.1-5% of crosslinking agent, 0.1-1% of thermosensitive acid, and the organic solvent of the remaining amount, where the body resin includes a light-absorbing functional group, a crosslinking functional group, and an auxiliary functional group.

### Embodiment III

Based on the polysilicon gate etch method of Embodiment I, in step S4, the cure flow rate is determined by selection based on the design linewidths of the polysilicon gates at various positions on the wafer, and a matrix table of a calibrated HBr gas flow rate and magnitudes of changes in linewidths of different structures after etch, so that different amounts of hydrogen bromide may be used to obtain linewidths desired by a user, improving the choosability of process integration.

The matrix table of the HBr gas flow rate and the magnitudes of changes in linewidths of different structures after etch is calibrated by a design of experiment (DOE) experiment method.

The matrix table of the HBr gas flow rate and the magnitudes of changes in linewidths of different structures after etch is shown in Table I and FIG. 7. In case of the same HBr gas injection flow rate, the smaller the linewidth, the larger the amount of narrowing of the linewidth; and in case of the same linewidth, the larger the HBr gas injection flow rate, the smaller the amount of narrowing of the linewidth.

TABLE I
Table of parameter variations in the cure step during the polysilicon gate etch process

| | Experiment | Experiment | Reference | Experiment | Experiment |
|---|---|---|---|---|---|
| | condition 1 | condition 2 | condition | condition 3 | condition 4 |
| HBr (SCCM) | 28 | 24 | 20 | 16 | 12 |
| CD Bias . . . ADI CD 60 nm | −7 | −8 | −10 | −12 | −14 |
| CD Bias . . . ADI CD 80 nm | −8 | −10 | −15 | −19 | −23 |
| CD Bias . . . ADI CD 100 nm | −9 | −12 | −20 | −26 | −32 |
| CD Bias . . . ADI CD 120 nm | −10 | −14 | −25 | −33 | −41 |

In some examples, during step S4, when the cure flow rate of HBr is determined by selection, design linewidths of the polysilicon gates of various structures and at various positions on the wafer are collected before the bottom anti reflection coating (BARC) is etched.

During step S5, widths of the hard mask layer (HM) at the polysilicon gates of various structures on the wafer are collected after the hard mask layer (HM) is etched.

A center design linewidth for the current process is determined based on the design linewidths of the polysilicon gates of various structures and at various positions on the wafer that are collected before the bottom anti reflection coating (BARC) is etched and during step S4 and the widths of the hard mask layer (HM) at the polysilicon gates of various structures on the wafer that are collected after the hard mask layer (HM) is etched and during step S5.

The center design linewidth is used as a centerline to establish a process window for the process, to ensure the stability of subsequent mass production.

The above descriptions are merely examples of the embodiments of the present disclosure and are not intended to limit the present disclosure. Any modifications, equivalent substitutions, improvements, etc. made within the spirit and principles of the present disclosure shall be included within the protection scope of the present disclosure.

What is claimed is:

1. A polysilicon gate etch method, comprising the following steps:
S1: sequentially forming a gate oxide layer, a polysilicon layer, a hard mask layer, a bottom anti reflection coating, and a photoresist on a silicon substrate;
S2: photoetching the photoresist according to design linewidths of polysilicon gates at various positions on a wafer;
S3: injecting an etch gas into an etch chamber, to remove the bottom anti reflection coating outside a polysilicon gate area by etch and retain the bottom anti reflection coating in the polysilicon gate area;
S4: injecting only an HBr gas into the etch chamber at a cure flow rate as an etch gas, to etch the bottom anti reflection coating, so that the anti reflection coating and the photoresist in the polysilicon gate area are further narrowed, reducing a width difference between the anti reflection coatings on the polysilicon gates at various positions on the wafer;
S5: etching the hard mask layer, to remove the hard mask layer not covered by the bottom anti reflection coating and retain the hard mask layer covered by the bottom anti reflection coating; and
S6: performing subsequent process steps to complete polysilicon gate etch.

2. The polysilicon gate etch method according to claim 1, wherein
step S6 comprises the following steps:
S61: performing hard mask layer cure etch to reduce the width of the hard mask layer at each polysilicon gate on the wafer by a corresponding magnitude;
S62: stripping the photoresist and the bottom anti reflection coating, and retaining the hard mask layer; and
S63: etching a polysilicon layer using the hard mask layer as a protective layer, to remove the polysilicon layer not covered by the hard mask layer and retain the polysilicon layer covered by the hard mask layer.

3. The polysilicon gate etch method according to claim 1, wherein
the etch gas injected into the etch chamber in step S3 comprises an HBr gas.

4. The polysilicon gate etch method according to claim 1, wherein
the hard mask layer is composed of at least one silicon oxide layer and/or a silicon nitride layer.

5. The polysilicon gate etch method according to claim 1, wherein
components of the bottom anti reflection coating comprise a body film-forming resin capable of cross-linking, a thermo acid generator, a crosslinking agent, and an organic solvent.

6. The polysilicon gate etch method according to claim 1, wherein
the bottom anti reflection coating comprises the following raw materials in mass percentages: 5-15% of aryl-containing glycoluril oligomer solution, 0.5-15% of body resin, 0.1-5% of crosslinking agent, 0.1-1% of thermosensitive acid, and the organic solvent of the remaining amount;
wherein the body resin comprises a light-absorbing functional group, a crosslinking functional group, and an auxiliary functional group.

7. The polysilicon gate etch method according to claim 1, wherein
in step S4, the cure flow rate is determined by selection based on the design linewidths of the polysilicon gates at various positions on the wafer, and a matrix table of a calibrated HBr gas flow rate and magnitudes of changes in linewidths of different structures after etch; and
the matrix table of the HBr gas flow rate and the magnitudes of changes in linewidths of different structures after etch is calibrated by a DOE experiment method.

8. The polysilicon gate etch method according to claim 1, wherein
during step S4, when the cure flow rate of HBr is determined by selection, design linewidths of the polysilicon gates of various structures and at various positions on the wafer are collected before the bottom anti reflection coating is etched;
during step S5, widths of the hard mask layer at the polysilicon gates of various structures on the wafer are collected after the hard mask layer is etched;
a center design linewidth for the current process is determined based on the design linewidths of the polysilicon gates of various structures and at various positions on the wafer that are collected before the bottom anti reflection coating is etched and during step S4 and the widths of the hard mask layer at the polysilicon gates of various structures on the wafer that are collected after the hard mask layer is etched and during step S5; and
the center design linewidth is used as a centerline to establish a process window for the process.
